(19) United States
(12) Patent Application Publication
(10) Pub. No.: US 2012/0110839 A1
(43) Pub. Date: May 10, 2012

(54) METHOD OF MANUFACTURING WIRING BOARD

(75) Inventors: Kenji NISHIO, Komaki-shi (JP); Masaki MURAMATSU, Nagoya-shi (JP); Masao IZUMI, Konan-shi (JP); Erina YAMADA, Komaki-shi (JP); Hironori SATO, Kasugai-shi (JP)

(73) Assignee: NGK SPARK PLUG CO., LTD., Nagoya-shi (JP)

(21) Appl. No.: 13/283,269

(22) Filed: Oct. 27, 2011

(30) Foreign Application Priority Data
Nov. 5, 2010 (JP) 2010-248562
Nov. 5, 2010 (JP) 2010-248563

(51) Int. Cl. H05K 3/36

(52) U.S. Cl. 29/830

(57) ABSTRACT

Disclosed is a manufacturing method of a wiring board with at least one conduction layer and at least one resin insulation layer. The manufacturing method includes an opening forming step of forming openings in the resin insulation layer and a paste filling step of filling a copper paste into the openings to form the conduction layer from the copper paste.

### BACKGROUND OF THE INVENTION

The present invention relates to a method of manufacturing a wiring board.

Multilayer fine wiring structures have recently been adopted for high-density packaging and high-speed performance of LSI devices. In particular, it is required for logic devices to reduce the minimum pitch of wiring lines according to the gate length of transistors in order to achieve high transistor performance. Fine wiring techniques are essential for such wiring pitch reduction.

Damascene processes, in which no metal etching treatment is required, are becoming the mainstream of fine wiring techniques in place of dry etching processes although the dry etching processes have conventionally been used as A1 wiring techniques. The damascene process includes the steps of forming openings such as wiring trenches and/or via holes in a resin insulation film by laser irradiation, applying a metal undercoat to the openings, depositing a Cu film by plating, and then, removing an excessive Cu plating deposit by chemical mechanical polishing (CMP) etc. from a surface of the resin insulation film to form wiring lines in the wiring trenches and/or via plugs (i.e. conductors for electrical connection to any underlying wiring) in the via holes. As discussed in e.g. Japanese Laid-Open Patent Publication No. 2007-116135 and Japanese Laid-Open Patent Publication No. 2006-049804, there are two types of damascene processes: a single-damascene process in which the wiring lines and the via plugs are formed separately from each other and a dual-damascene process in which the wiring lines and the via plugs are formed at one time.

In both of the single-damascene process and the dual-damascene process, the Cu plating film is deposited on the whole of the resin insulation film. When the width or diameter (area) of the openings is large, there occur depressions in the Cu plating film at around the centers of the openings in width or diameter directions thereof due to insufficient plating so that the Cu plating film cannot be formed with a uniform thickness in such a manner as to fill in the openings. This results in a failure to manufacture a wiring board with desired electrical characteristics such as wiring impedance. Further, the damascene wiring process and by extension the manufacturing process of the wiring board is somewhat complicated due to the need to perform the polishing treatment for removal of the excessive Cu plating deposit.

It is conceivable that the Cu plating film could be deposited with a large thickness so as to avoid the occurrence of depressions in the Cu plating film at around the centers of the openings. In such a case, however, the amount of the excessive Cu plating deposit that needs to be removed by the subsequent polishing treatment from the surface of the resin insulation film becomes increased to thereby cause a deterioration in workability during the manufacturing of the wiring board as well as an unfavorable result in terms of resource saving.

### SUMMARY OF THE INVENTION

In view of the foregoing, it is an object of the present invention to provide a novel manufacturing method of a wiring board, by which a conduction layer can be formed uniformly in openings of a resin insulation layer irrespective of the width or diameter (area) of the openings and without complicated process steps.

According to an aspect of the present invention, there is provided a method of manufacturing a wiring board, the wiring board comprising at least one conduction layer and at least one resin insulation layer, the method comprising: an opening forming step of forming openings in a main surface of the resin insulation layer; and a paste filling step of filling a copper paste into the openings to form the conduction layer from the copper paste.

The conduction layer constitutes both of wiring lines and vias in the case where some of the openings are formed so as to pass through the resin insulation layer so that any underlying wiring becomes exposed through these some openings as will be described in the following embodiment. On the other hand, the conduction layer constitutes only wiring lines in the case where the openings are formed so as not to pass through the resin insulation layer.

There is no particular on the means for filling the copper paste into the openings. The copper paste can be filled into the openings by various means. It is preferable to fill the copper paste in the openings by at least one selected from the group consisting of a squeegee process, a roll coater process, a spray coater process, a curtain coater process, a slit coater process, a dip coater process, a gravure coater process and a die coater process. It is also preferable to fill the copper paste in the openings by an ink-jet process using an ink-jet device.

The other objects and features of the present invention will also become understood from the following description.

### BRIEF DESCRIPTION OF THE DRAWINGS

FIGS. 1 and 2 are top and bottom plan views of a wiring board according to one embodiment of the present invention, respectively.

FIG. 3 is a section view of part of the wiring board taken along a line I-I of FIGS. 1 and 2.

FIG. 4 is a section view of part of the wring board taken along a line II-II of FIGS. 1 and 2.

FIGS. 5 to 11 are schematic views showing process steps for manufacturing the wiring board according to the one embodiment of the present invention.

FIG. 12 is a schematic view of a squeegee process as an example of Cu paste filling means during the manufacturing of the wiring board according to the one embodiment of the present invention.

FIG. 13 is a schematic view of a roll coater process as an example of Cu paste filling means during the manufacturing of the wiring board according to the one embodiment of the present invention.

FIG. 14 is a schematic view of a spray coater process as an example of Cu paste filling means during the manufacturing of the wiring board according to the one embodiment of the present invention.

FIG. 15 is a schematic view of a curtain (flow) coater process as an example of Cu paste filling means during the manufacturing of the wiring board according to the one embodiment of the present invention.

FIG. 16 is a schematic view of a slit coater process as an example of Cu paste filling means during the manufacturing of the wiring board according to the one embodiment of the present invention.

FIG. 17 is a schematic view of a dip coater process as an example of Cu paste filling means during the manufacturing of the wiring board according to the one embodiment of the present invention.

FIG. 18 is a schematic view of a gravure coater process as an example of Cu paste filling means during the manufacturing of the wiring board according to the one embodiment of the present invention.

FIG. 19 is a schematic view of a die coater process as an example of Cu paste filling means during the manufacturing of the wiring board according to the one embodiment of the present invention.

FIGS. 20 to 23 are schematic view of an ink-jet process as an example of Cu paste filling means during the manufacturing of the wiring board according to the one embodiment of the present invention.

FIGS. 24 to 28 are schematic views showing process steps for manufacturing the wiring board according to the one embodiment of the present invention.

### DESCRIPTION OF THE EMBODIMENTS

The present invention will be described in detail below with reference to the drawings. For the sake of clearness, some parts in these drawings may not be hatched even when viewed in cross section. Further, the directional terms such as “top”, “bottom”, “inner” and “outer” are herein used for illustration purposes only and are not intended to limit the present invention to any particular orientation.

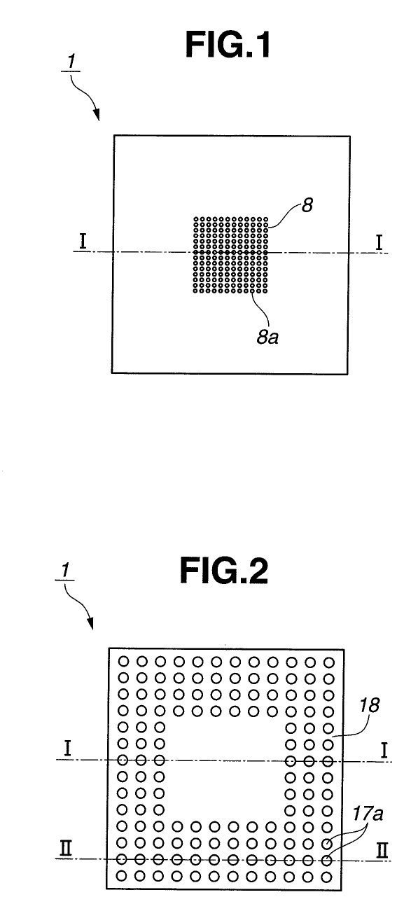

The following embodiment specifically refers to a multilayer wiring board 1 as shown in FIGS. 1 to 4 although the present invention can be applied to any type of wiring board having at least one conduction layer and at least one resin insulation layer.

Structure of Wiring Board

The structure of the wiring board 1 will be first explained below.

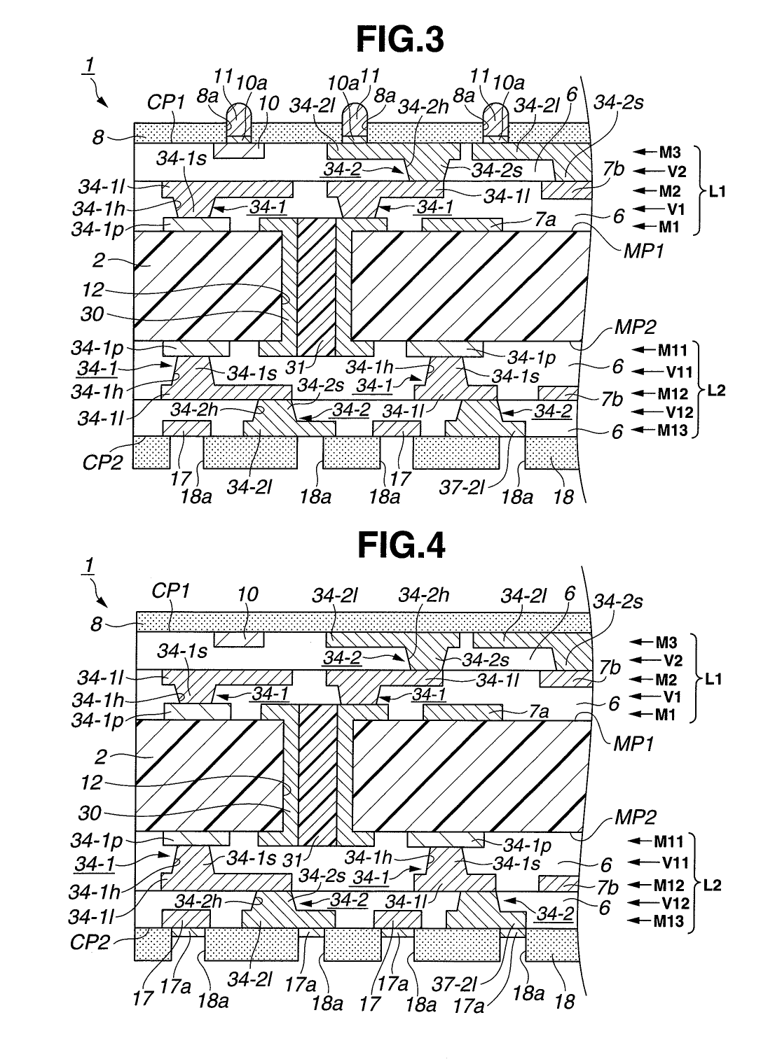

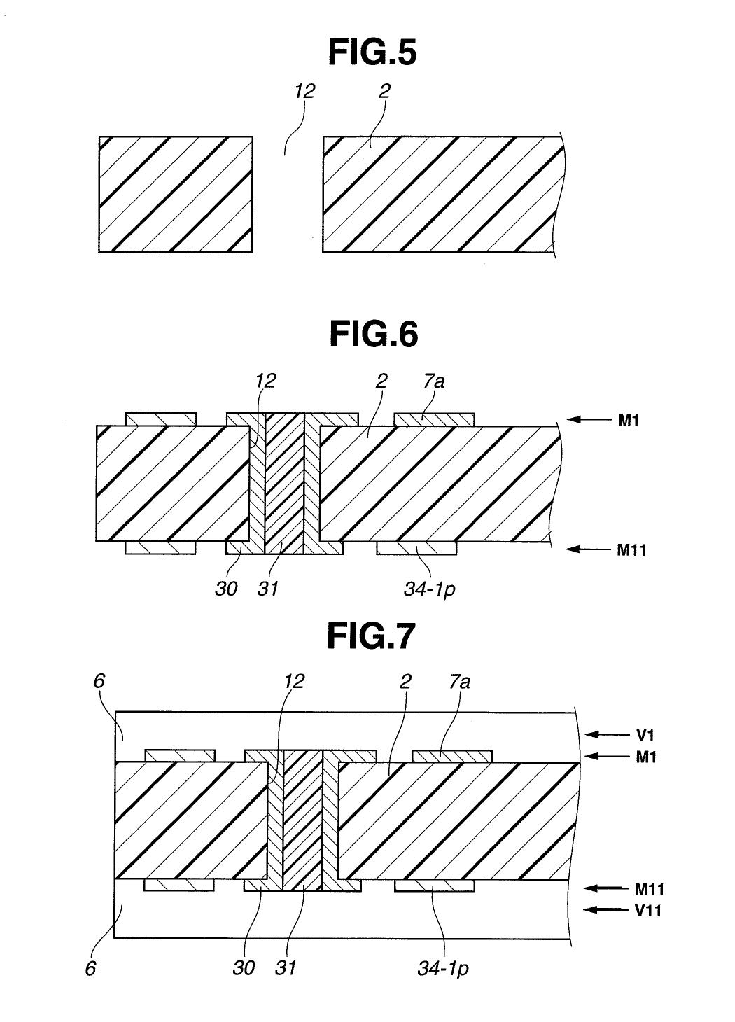

As shown in FIGS. 3 and 4, the wiring board 1 includes a core substrate 2, core conduction layers M1 and M11, first resin insulation layers V1 and V11 (build-up layers: via layers), first conduction layers M2 and M12, second resin insulation layers V2 (build-up layers: via layers) and V12 and second conduction layers M3 and M13.

As the core substrate 2, there can be used a plate of heat-resistant resin such as bismaleimide-triazine resin or fiber-reinforced resin such as glass fiber-reinforced epoxy resin.

The conduction layers M1 and M11 are arranged on first and second (top and bottom) main surfaces MP1 and MP2 of the core substrate 2, respectively. Each of the conduction layers M1 and M11 includes metal wiring lines 7a formed according to a predetermined pattern. In the present embodiment, the conduction layer M1, M11 is in the form of a planar conductive pattern that covers most of the main surface MP1, MP2 of the core plate 2 and is used as a power source layer or a ground layer.

Through holes 12 are made through the core substrate 2 by drilling etc. Through hole conductors 30 are formed on inner circumferential surfaces of the though holes 12 for electrical connection between the conduction layers M1 and M11. The through holes 12 (the insides of the through hole conductors 30) are each filled with a resin filling material 31 such as epoxy resin.

The first resin insulation layers V1 and V11 are arranged on outer main surfaces of the conduction layers M1 and M11, respectively. These first resin insulation layers V1 and V11 are formed of a thermosetting resin composition 6 to which a filler such a silica filler etc. may be added as needed.

The first conduction layers M2 and M12 are embedded in outer main surfaces of the first resin insulation layers V1 and V11, respectively. Each of the conduction layers M2 and M12 includes metal wiring lines 7b formed according to a predetermined pattern. The wiring line 7b has an outer surface exposed at the outer main surface of the first resin insulation layer V1, V11 so that the outer surface of the wiring line 7b (the outer main surface of the first conduction layer M2, M12) and the outer main surface of the first resin insulation layer V1, V11 are in the same plane level. Each of the first conduction layers M2 and M12 also includes filled vias 34-1 formed through the first resin insulation layers V1 and V11 for electrical connection to the core conduction layer M1, M11. The filled via 34-1 has a via hole 34-1h, a via conductor 34-1s embedded in the via hole 34-1h, a via pad 34-1p connected to an inner end of the via conductor 34-1s and a via land 34-1l connected to and projecting radially from an outer end of the via conductor 34-1s. The via land 34-1l has an outer surface exposed at the outer main surface of the first resin insulation layer V1, V11 so that the outer surface of the via land 34-1l and the outer main surface of the first resin insulation layer V1, V11 are in the same plane level.

The second resin insulation layers V2 and V12 are arranged on the outer main surfaces of the first conduction layers M1 and M11 and on the outer main surfaces of the first conduction layers M2 and M12, respectively. These second resin insulation layers V2 and V12 are also formed of a thermosetting resin composition 6 to which a filler such a silica filler etc. may be added as needed.

The second conduction layers M3 and M13 are arranged on outer main surfaces of the second resin insulation layers V2 and V12, respectively. The second conduction layer M3 includes a plurality of metal terminal pads 10 formed at an outer main surface thereof, whereas the second conduction layer M13 includes a plurality of metal terminal pads 17 formed at an outer main surface thereof. Each of the second conduction layers M3 and M13 also includes filled vias 34-2 formed through the second resin insulation layers V2 and V12 for electrical connection to the first conduction layers M2 and M12. The filled via 34-2 has a via hole 34-2h, a via conductor 34-2s embedded in the via hole 34-2h and a via land 34-2l projecting radially from an outer end of the via conductor 34-2s and connected to the via land 34-1l or the wiring line 7b.

In the present embodiment, the first conduction layer M2, M12 constitutes the wiring lines 7b and the vias 34-1 (via conductors 34-1s and via lands 34-1l); and the second conduction layer M3, M13 constitutes the metal terminal pads 10, 17 and the vias 34-2 (via conductors 34-2s and via lands 34-2l). The after-mentioned manufacturing method of the present invention is applied to these conduction layers M2, M12, M3 and M13.

As mentioned above, the core conduction layer M1, the first resin insulation layer V1, the first conduction layer M2, the second resin insulation layer V2 and the second conduction layer M3 are formed sequentially on the first main surface MP1 of the core plate 2, thereby defining a first laminated wiring portion L1 with a plurality of metal terminal pads 10 arranged on a first main surface CP1 of the wiring board 1. Further, the core conduction layer M11, the first resin insulation layer V11, the first conduction layer M12, the second resin insulation layer V12 and the second conduction layer M13 are formed sequentially on the second main surface MP2 of the core plate 2, thereby defining a second laminated wiring portion L2 with a plurality of metal terminal pads 17 arranged on a second main surface CP2 of the wiring board 1.

The wiring board 1 further includes solder resist layers 8 and 18 and laminated films 10a and 17a as shown in FIGS. 1 to 4.

The solder resist layer 8 is formed with openings 8a on the first main surface CP1 of the wiring board 1 so that the metal terminal pads 10 and the via lands 34-2l are exposed through the openings 8a.

The laminated films 10a are formed by electroless plating on the metal terminal pads 10 and the via lands 34-2l. In the present embodiment, the laminated films 10a each contain nickel and gold.

The solder resist layer 18 is formed with openings 18a on the second main surface CP2 of the wiring board 1 so that the metal terminal pads 17 and the via lands 34-2l are exposed through the openings 18a.

The laminated films 17a are formed on the metal terminal pads 17 and the via lands 34-2l. These laminated films 17a also each contain nickel and gold in the present embodiment. Alternatively, the laminated films 17a may not be formed such that the metal terminal pads 17 and the via lands 34-2l are directly exposed to the outside through the openings 18a.

Furthermore, solder bumps 11 are formed in the openings 8a of the solder resist layer 8, by substantially lead-free soldering such as Sn—Ag, Sn—Cu, Sn—Ag—Cu or Sn—Sb, for electrical connection to the metal terminal pads 10 and the via lands 34-2l. Although not shown in the drawings, solder balls or pins are formed in the openings 18a of the solder resist layer 18 for electrical connection to the metal terminal pads 17 and the via lands 34-2l.

As seen from FIGS. 1 to 4, the wiring board 1 has a substantially rectangular plate shape whose size is, for example, about 35 mm×about 35 mm×about 1 mm, in the present embodiment.

Manufacturing Method of Wiring Board

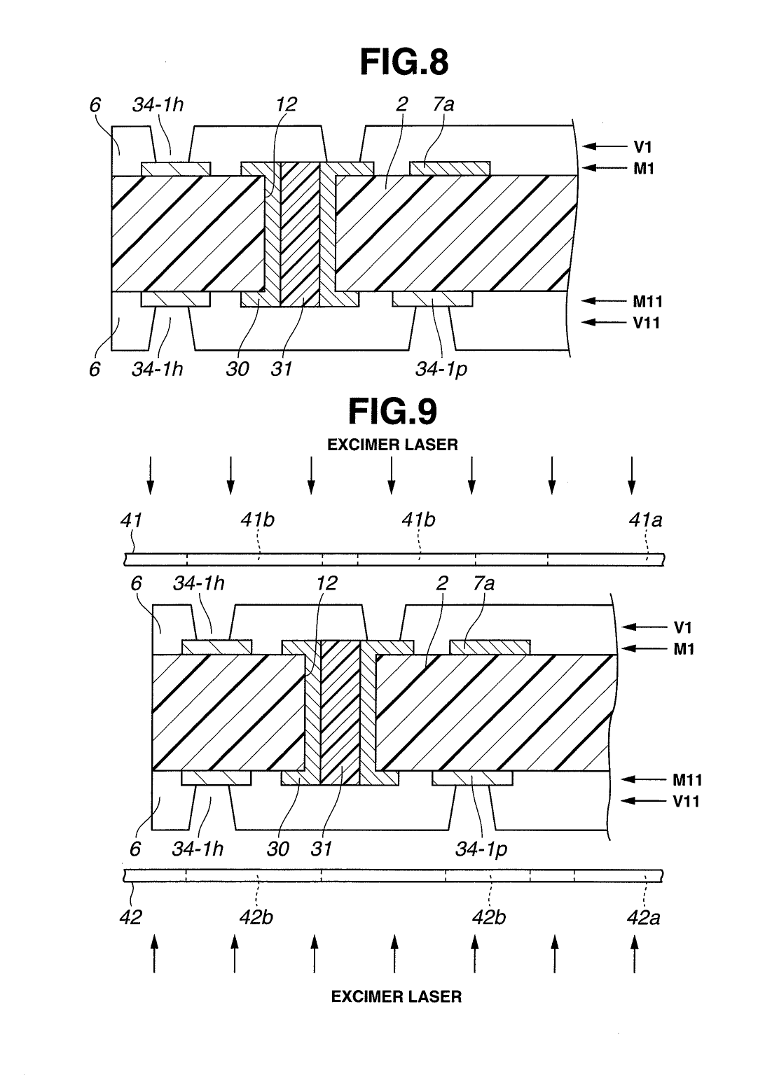

The manufacturing method of the wiring board 1 will be next explained below with reference to FIGS. 5 to 28. It is herein noted that FIGS. 5 to 12 and 19 to 28 are views corresponding to FIG. 3 as viewed in cross section along a line I-I of FIGS. 1 and 2.

First, the core substrate 2 is prepared. As shown in FIG. 5, the through holes 12 are made by drilling etc. through the core substrate 2. The core conduction layers M1 and M11, the through hole conductors 30 and the via pads 34-1p are formed by pattern plating, and then, the resin filling material 31 is filled in the through holes 12 (the insides of the through hole conductors 30) as shown in FIG. 6.

As shown in FIG. 7, the insulation layers V1 and V11 are formed by, after subjecting the core conduction layers M1 and M11 to roughening treatment, laminating films of the resin composition 6 on the core conduction layers M1 and M11 so as to cover the conduction layers M1 and M11 (wiring lines 7a), the through hole conductors 30 and the via pads 34-1p with the films of the resin composition 6, and then, hardening the films of the resin composition 6. As mentioned above, the filler may be contained in the resin composition 6 as needed.

Openings are next formed by laser irradiation in the insulation layers V1 and V11.

More specifically, the outer main surfaces of the insulation layers V1 and V11 are irradiated with a CO₂ gas laser or a UV gas laser to thereby form the via holes 34-1h through the insulation layers V1 and V11 according to a predetermined pattern as shown in FIG. 8. The intensity (output) of the CO₂ gas laser or UV gas laser is set to, for example, 10 to 200 W. After that, the insulation layers V1 and V11 with the via holes 34-1h are subjected to roughening treatment.

When the filler is contained in the insulation layers V1 and V11, the filler is liberated onto the insulation layers V1 and V11 by the roughening treatment. The liberated filler is removed by water washing treatment (e.g. high-pressure water washing) etc. as appropriate.

Subsequently, the insides of the via holes 34-1h are cleaned by desmear treatment and outline etching treatment. As the liberated filler has been removed by the water washing treatment as mentioned above, it is possible to prevent agglomeration of the filler by water washing during the desmear treatment.

Air blowing treatment may be performed between the water washing treatment and the desmear treatment. Even when the liberated filler has not yet been completely removed by the water washing treatment, it is possible to complement the removal of the filler by the air blowing treatment.

As shown in FIG. 9, a first mask 41 with openings 41a and 41b and a second mask 42 with openings 42a and 42b are placed over the insulation layers V1 and V11, respectively, and then, an excimer laser is irradiated onto the outer main surfaces of the insulation layers V1 and V11 through the masks 41 and 42. The intensity (output) of the excimer laser is set to, for example, 10 to 200 W. As a result of the laser irradiation, wiring trenches 6a for the wiring lines 7b are formed in the insulation layers V1 and V11 at positions corresponding to the openings 41a and 42a of the masks 41 and 42; and trenches 6b for the via lands 34-1l are formed in the insulation layers V1 and V11 at positions corresponding to the openings 41b and 42b of the masks 41 and 42 as shown in FIG. 10. Herein, the trenches 6b for the via lands 34-1l are regarded as falling under the category of wiring trenches as the wiring lines 7b, the via conductors 34-1s and the via lands 34-1l establish wiring (pattern) so that the via lands 34-1l constitutes a part of the wiring to make electrical connection with any wiring (not shown) through the via pads 34-1p.

If trenches are formed in a resin insulation layer sequentially by spot irradiation with an excimer laser, there occur variations in trench edge shape due to spot processing operations as well as variations in trench depth due to repeated spot processing operations.

In the present embodiment, by contrast, the trenches 6a and 6b are formed at one time by surface irradiation with the excimer laser as mentioned above. As there can be prevented variations in the edge shape and depth of the trenches 6a and 6b so as to limit variations in the shape and thickness of the wiring lines 7b in the trenches 6a and variations in the shape and thickness of the via lands 34-1l in the trenches 6b, it is possible to avoid a deviation of the impedance of the wiring (notably, the impedance of the wiring lines 7b) from its design value and prevent a deterioration in the manufacturing yield of the wiring board 1.

When the wiring board 1 is relatively large in size, the trenches 6a and 6b can be formed in the insulation layers V1 and V11 sequentially by moving the excimer laser and the first and second masks 41 and 42 as appropriate.

Further, the trenches 6a and 6b are formed so as not to pass through the insulation layers V1 and V11.

In the present embodiment, the trenches 6a and 6b are formed by the surface radiation with the excimer laser after the formation of the via holes 34-1h by the irradiation with the CO₂ gas or UV gas laser as mentioned above. As the excimer laser is irradiated onto the bottoms of the via holes 34-1h during the formation of the trenches 6a and 6b, any processing residue remaining on the bottoms of the via holes 34-1h in the insulation layers V1 and V11 can be removed and cleaned up by the surface irradiation with the excimer laser. It is thus possible to omit the water washing during the desmear treatment or the subsequent air blowing treatment.

The via holes 34-1h may alternatively be formed by general-purpose wet or dry etching treatment in place of the CO₂ gas or UV gas laser irradiation. Further, the trenches 6a and 6b may alternatively be formed by general-purpose wet or dry etching treatment in place of the excimer laser surface irradiation.

The resulting laminate of the core substrate 2, the conduction layers M1 and M11 and the insulation layers V1 and V11 with the via holes 34-1h and the trenches 6a and 6b as shown in FIG. 10 is hereinafter simply referred to as “a laminated body” for illustration purposes.

As shown in FIG. 11, a Cu paste is fed and filled into the via holes 34-1h and the trenches 6a and 6b to thereby form the via conductors 34-1s in the via holes 34-1h, form the wiring lines 7b in the trenches 6a and form the via lands 34-1l in the trenches 6b. With this, the patterned conduction layers M2 and M12 are obtained.

As the trenches 6a are formed so as not to pass through the insulation layers V1 and V11 as mentioned above, the wiring lines 7b can be arranged in the form of being embedded in the insulation layer V1, V11. It is possible by such an embedded arrangement to prevent fall off of the wiring lines 7b even when the wiring lines 7b are made fine.

There is no particular on the means for feeding and filing the Cu paste. The Cu paste can be fed and filled by various means.

It is preferable to feed and fill the Cu paste by at least one selected from the group consisting of a squeegee process, a roll coater process, a spray coater process, a curtain (flow) coater process, a slit coater process, a dip coater process, a gravure coater process and a die coater process. Each of these processes is advantageous in that it allows easy feeding and filling of the Cu paste into the via holes 34-1h and the trenches 6a and 6b.

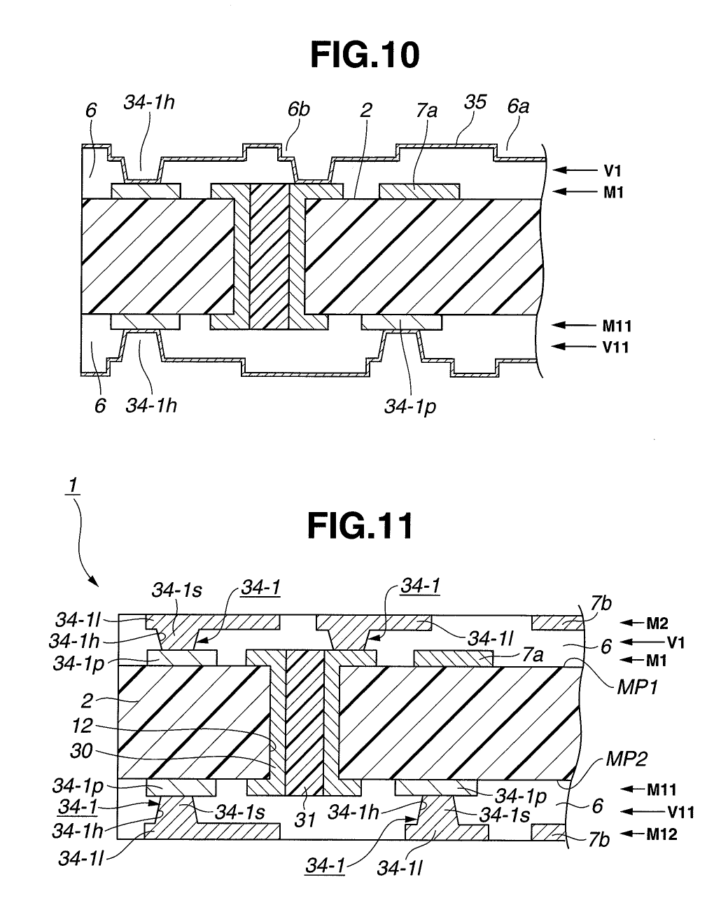

In the squeegee process, a plate member called “a squeegee 42” is used as the Cu paste feeding/filling mean a shown in FIG. 12. The Cu paste is fed and filled into the via holes 34-1h and the trenches 6a and 6b by placing a piece of Cu paste 41 and spreading the Cu paste 41 by the squeegee 42 over the outer main surface of the insulation layer V1, V11.

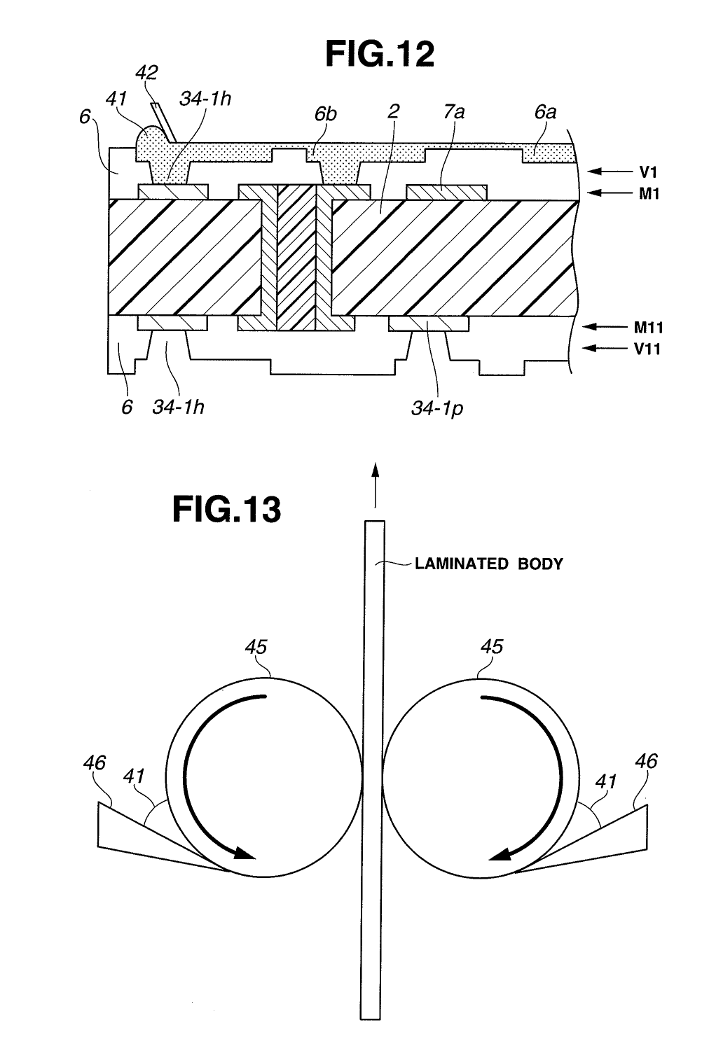

In the roll coater process, a so-called “roll coater” is used as the Cu paste feeding/filling mean. The roll coater has a pair of rollers 45 equipped with doctor bars 46, respectively, as shown in FIG. 13. The Cu paste is fed and filled into the via holes 34-1h and the trenches 6a and 6b by feeding Cu paste 41 from the doctor bars 46 to surface recesses of the rollers 45 and then to the laminated body while passing the laminated body through between the rollers 45.

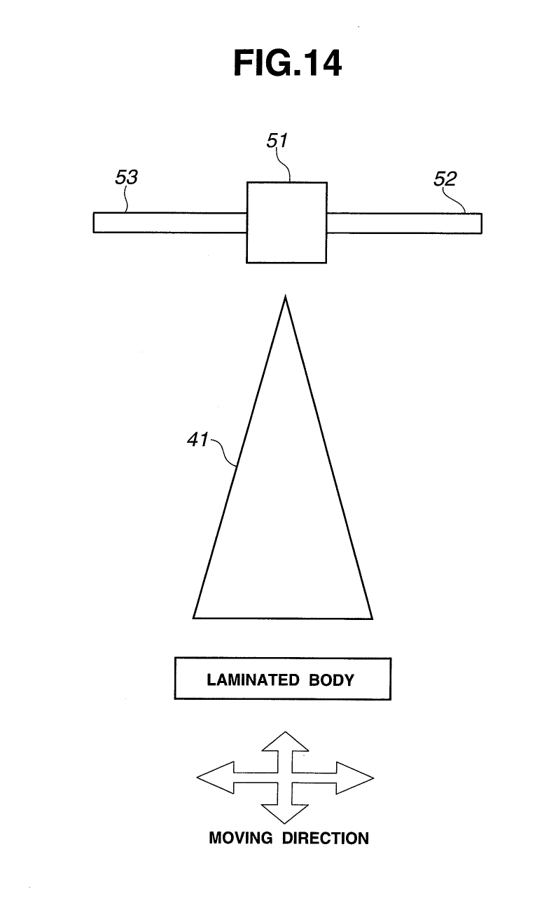

In the spray coater process, a so-called “spray coater” is used as the Cu paste feeding/filling mean. As shown in FIG. 14, the spray coater has a nozzle 51, a Cu paste feed pipe 52 connected to the nozzle 51 and a mixed gas pipe 53 connected to the nozzle 51. The Cu paste is fed and filled into the via holes 34-1h and the trenches 6a and 6b by moving the laminated body in the direction of arrows while feeding Cu paste 41 and mixed gas to the nozzle 51 through the Cu paste feed pipe 52 and the mixed gas pipe 53, respectively, to thereby spraying the Cu paste 41 from the nozzle 51 to the laminated body.

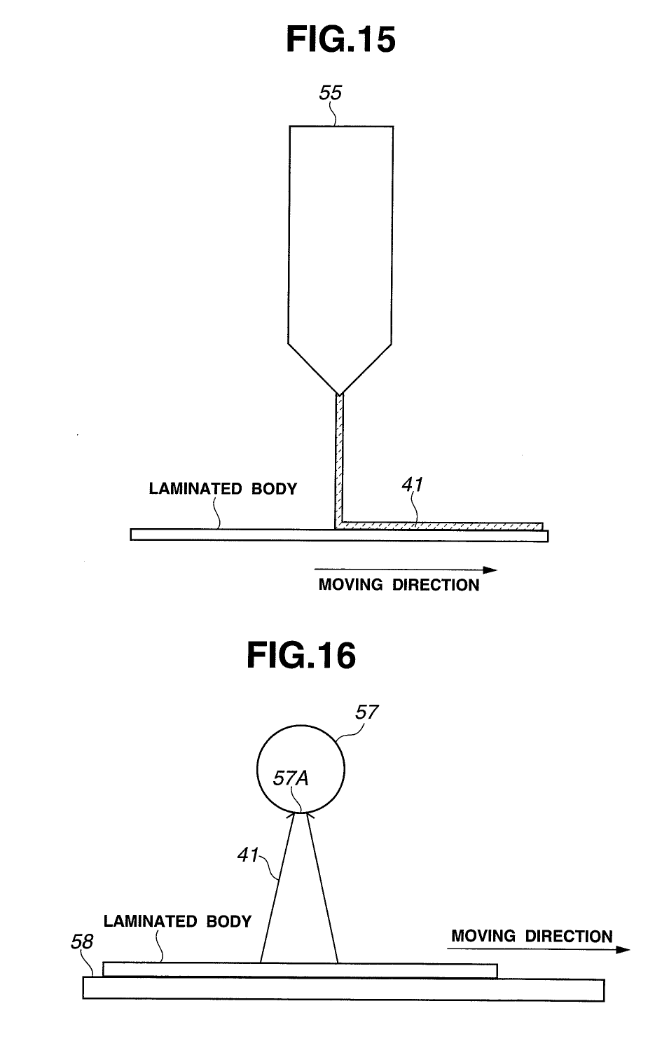

In the curtain (flow) coater process, a so-called “curtain (flow) coater” is used as the Cu paste feeding/filling mean. As shown in FIG. 15, the curtain (flow) coater has a head 55 in which Cu paste 41 is charged. The Cu paste is fed and filled into the via holes 34-1h and the trenches 6a and 6b by moving the laminated body in the direction of an arrow while ejecting a continuous flow of the Cu paste 41 in curtain form from the head 55 to the laminated body.

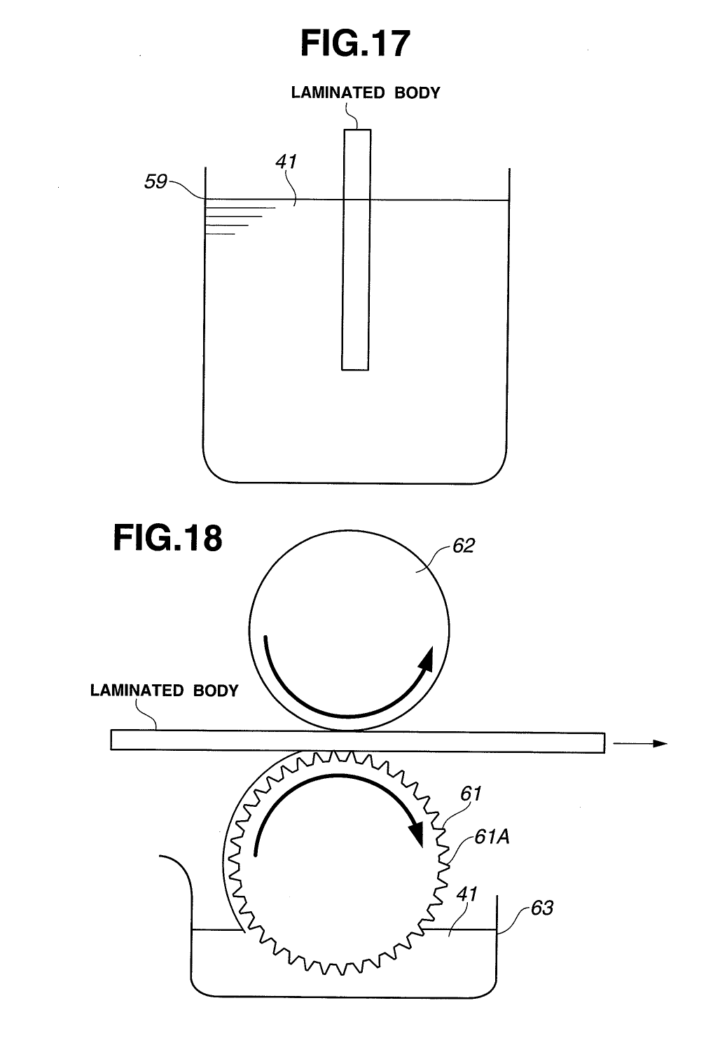

In the slit coater process, a so-called “slit coater” is used as the Cu paste feeding/filling mean. In ordinary cases, there can be used any general-purpose slit coater. Generally, the slit coater has a nozzle 57 formed with a slit 57A in a length direction thereof and a transfer stage 58 as shown in FIG. 16. The Cu paste is fed and filled into the via holes 34-1h and the trenches 6a and 6b by moving the laminated body with the transfer stage 58 in the direction of an arrow while ejecting Cu paste 41 from the nozzle 57 (slit 57A) to the laminated body.

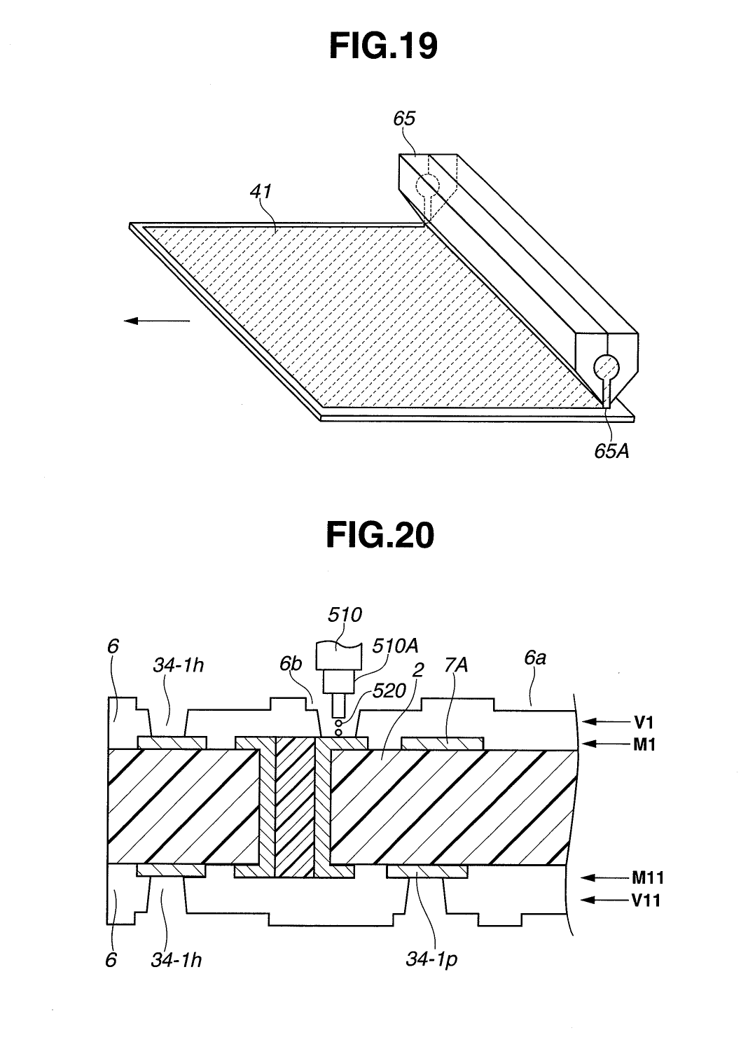

In the dip coater process, a so-called “dip coater” is used as the Cu paste feeding/filling mean. As shown in FIG. 17, the dip coater has a container 59 in which Cu paste 41 is charged. The Cu paste is fed and filled into the via holes 34-1h and the trenches 6a and 6b by dipping the laminated body into the Cu paste 41 in the container 59 and thereby applying the Cu paste 41 to the laminated body.

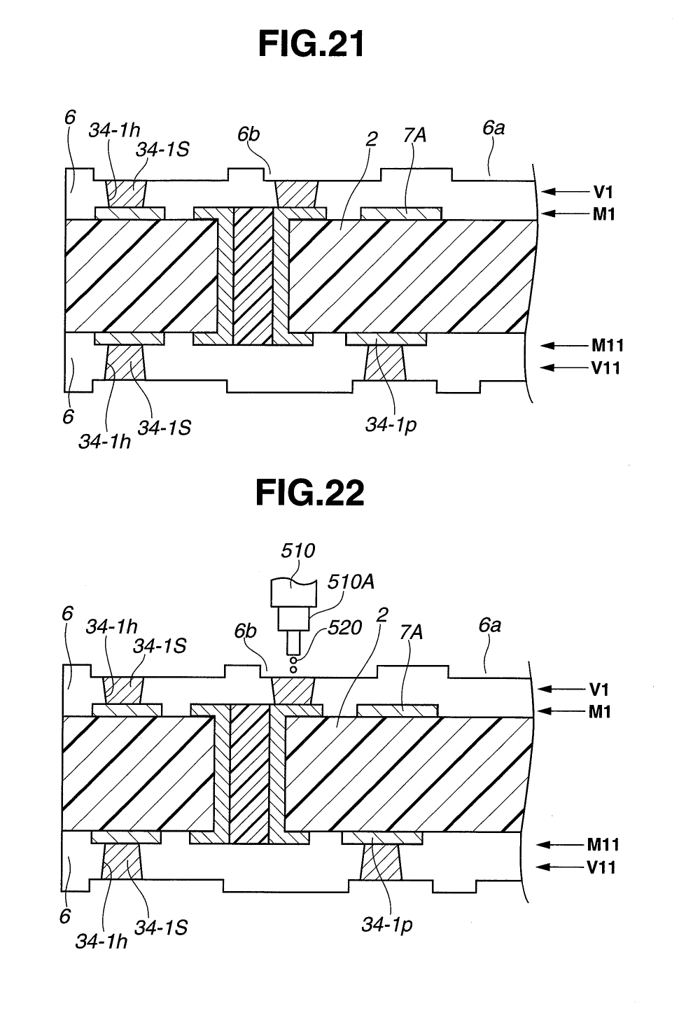

In the gravure coater process, a so-called “gravure coater” is used as the Cu paste feeding/filling mean. The gravure coater has a gravure roll 61 formed with recesses 61A, a back up roll 62 opposed to the gravure roll 61 and a container 63 containing therein Cu paste 41 and located below the gravure roll 61 so that the recesses 61A come into contact with the Cu paste 41a shown in FIG. 18. The Cu paste is fed and filled into the via holes 34-1h and the trenches 6a and 6b by placing and moving the laminated body between the gravure roll 61 and the back up roll 62 in the direction of an arrow upon rotation of the gravure roll 61 and the back up roll 62 while applying the Cu paste 41 from the recesses 61A of the gravure roll 61 to the laminated body.

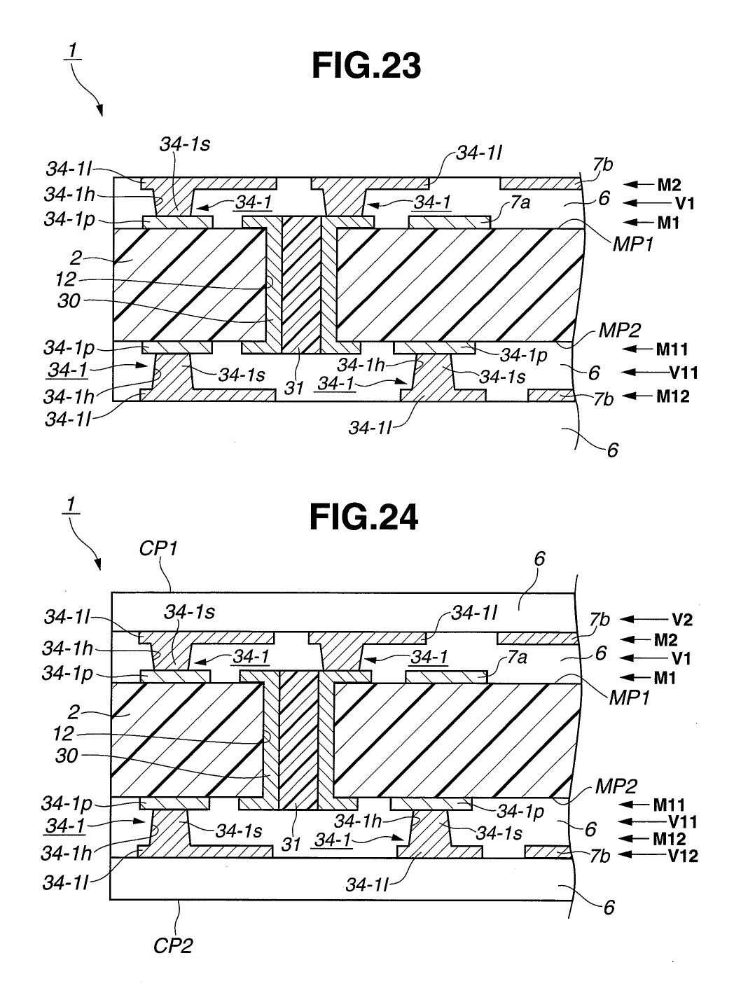

In the die coater process, a so-called “die coater” is used as the Cu paste feeding/filling mean. In ordinary cases, there can be used any general-purpose die coater. As shown in FIG. 19, the die coater generally has a head 65 formed with a lip 65A in a length direction thereof and a transfer stage (not shown). The Cu paste is fed and filled into the via holes 34-1h and the trenches 6a and 6b by moving the laminated body with the transfer stage in the direction of an arrow while allowing the head 65 (lip 65A) to eject Cu paste 41 onto the laminated body along a width direction thereof.

In the squeegee process, the roll coater process, the spray coater process, the curtain (flow) coater process, the slit coater process, the dip coater process, the gravure coater process or the die coater process, the Cu paste is fed not only to the via holes 34-1h and the trenches 6a and 6b but also to the outer main surface of the insulation layer V1, V11 as shown in FIG. 12. The Cu paste fed to the outer main surface of the insulation layer V1, V11 may remain as a Cu paste residue. In this case, the Cu paste residue is removed by polishing treatment such as chemical mechanical polishing (CMP) as appropriate.

As described above, the squeegee process, the roll coater process, the spray coater process, the curtain (flow) coater process, the slit coater process, the dip coater process, the gravure coater process and/or the die coater process is one preferred example of Cu paste feeding/filling mean. In the squeegee process, the roll coater process, the spray coater process, the curtain (flow) coater process, the slit coater process, the dip coater process, the gravure coater process and/or the die coater process, the Cu paste is directly fed and filled into the via holes 34-1h and the trenches 6a and 6b as the material of the via conductors 34-1s, the wiring lines 7b and the via lands 34-1l. The required amount of Cu paste can be thus filled into the required opening area, i.e., the via holes 34-1l and the trenches 6a and 6b. Further, the Cu paste can be filled uniformly into the via holes 34-1h and the trenches 6a and 6b even when the via holes 34-1h and the trenches 6a and 6b are large in width or diameter (area). It is therefore possible to form the via conductors 34-1s, the wiring lines 7b and the via lands 34-1l (the conduction layers M2 and M12) uniformly from the Cu paste without causing depressions in the via conductors 34-1s, the wiring lines 7b and the via lands 34-1l at around the centers of the via holes 34-1h, the trenches 6a and the trenches 6b, respectively, so that the wiring board 1 can be easily manufactured to achieve its desired electrical characteristics such as the impedance of the wiring.

As the required amount of Cu paste can be filled in the required opening area i.e. the via holes 34-1l and the trenches 6a and 6b, it is possible to significantly reduce the amount of the Cu paste residue that remains on the surface of the insulation layer V1, V11 and needs to be removed by the subsequent polishing treatment. This leads to not only an improvement in workability during the manufacturing of the wiring board 1 but also a favorable resource saving.

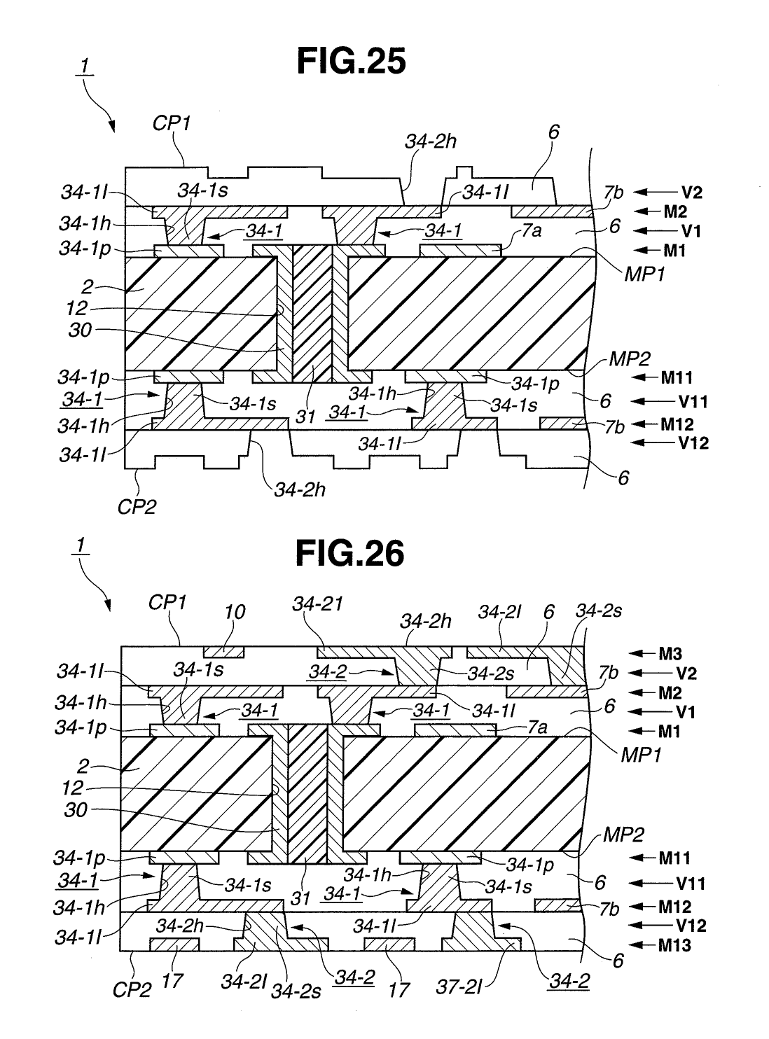

It is also preferable to feed and fill the Cu paste by an ink-jet process using an ink-jet device 510 as shown in FIGS. 20 to 23. As shown in FIG. 20, the ink-jet device 510 generally has a tip end portion 510A formed with a discharge hole.

Preferably, the ink-jet device 510 is in the form of at least one of a thermal ink-jet device and a piezoelectric ink jet device. Both of the thermal ink-jet device and the piezoelectric ink-jet device are readily available at low cost and are able to fill the Cu paste favorably into the via holes 34-1h and the trenches 6a and 6b.

For example, the via conductors 34-1s are first formed in the via holes 34-1h as shown in FIG. 21 by placing the tip end portion 510A (discharge hole) of the ink-jet device 510 in the via hole 34-1h and discharging Cu paste 520 from the discharge hole of the ink-jet device 510 into the via hole 34-1h as shown in FIG. 20. After that, the wiring lines 7b and the via lands 34-1l are formed in the trenches 6a and 6b, respectively, as shown in FIG. 23 by placing the tip end portion 51A (discharge hole) of the ink-jet device 510 in the trenches 6a, 6b and discharging Cu paste 520 from through the discharge hole of the ink-jet device 510 into the trench 6a, 6b as shown in FIG. 22. With this, the patterned conduction layers M2 and M12 are obtained.

The Cu paste is not necessarily discharged by locating the tip end portion 510A (discharge hole) of the ink-jet device 510 within the via hole 34-1h or the trench 6a, 6b. However, it is preferable to start discharging the Cu paste from the discharge hole of the ink-jet device 510 in a state that the tip end portion 510A (discharge hole) of the ink-jet device 510 is located within the via hole 34-1h and the trench 6a, 6b as mentioned above. This makes it possible to prevent scattering of the Cu paste and fill the Cu paste into the required opening area i.e. the via hole 34-1h and the trench 6a, 6b assuredly.

Needless to say, the trenches 6a, 6b and the via holes 34-1h are different in depth from each other. More specifically, the via holes 34-1h are made deeper than the trenches 6a, 6b. In this case, it is preferable to fill the Cu paste into the trenches 6a, 6b after filling the Cu paste into the via holes 34-1h as mentioned above for improvements in the uniformity of the wiring lines 7b and the via lands 34-1l.

As described above, the ink-jet process is another preferred example of Cu paste feeding/filling means. In the ink-jet process, the Cu paste is directly fed and filled into the via holes 34-1h and the trenches 6a and 6b as the material of the via conductors 34-1s, the wiring lines 7b and the via lands 34-1l. The required amount of Cu paste can be filled in the required opening area i.e. the via holes 34-1l and the trenches 6a and 6b by controlling the opening size of the discharge hole of the ink-jet device 510 and the amount of discharge of the Cu paste as appropriate. It is therefore possible to fill the adjusted amount of Cu paste according to the size (width and depth) of the via holes 34-1h and the trenches 6a and 6b in such a manner that the Cu paste fills in the via holes 34-1h and the trenches 6a and 6b but does not deposit as a residue on the surface of the insulation layer V1, V11. There is no need for the subsequent polishing treatment such as CMP to remove such a Cu paste residue. This allows simplification of the wiring process (the process of formation of the via conductors 34-1s, the wiring lines 7b and the via lands 34-1l) and by extension the manufacturing process of the wiring board 1.

In the case of discharging a Cu paste by an ink-jet process, it may be difficult to apply the Cu paste with a sufficient thickness or difficult to apply the Cu paste in continuous form.

In the case of discharging the Cu paste into the via holes 34-1h and the trenches 6a and 6b by the ink-jet process, however, the discharged Cu paste is held and pressed by walls of the via holes 34-1h and the trenches 6a and 6b. It is thus possible to apply the Cu paste in substantially continuous form, rather than in spot form, and ensure the sufficient application thickness and form of the Cu paste so that the conduction layer M2, M12 can be formed with a suitable wiring thickness and form. The above-mentioned drawback of the ink-jet process can be overcome in the case of discharging the Cu paste into the via holes 34-1h and the trenches 6a and 6b. There arises no problem of electrical connection failure as the via conductors 34-1s, the wiring lines 7b and the via lands 34-1l are formed in continuous form.

As shown in FIG. 10, Cu undercoat layers 35 may be formed by e.g. electroless plating in the via holes 34-1h and the trenches 6a and 6b before feeding and filling the Cu paste. (For the sake of clearness, the undercoat layers 35 are illustrated in only FIG. 10 and omitted from the other drawings.) When the Cu paste is filled in the via holes 34-1h and the trenches 6a and 6b, these undercoat layers 35 function as adhesion layers against the Cu paste. This makes it possible to increase adhesion of the Cu paste to the via holes 34-1h and the trenches 6a and 6b and prevent separation of the Cu paste from the via hole 34-1h and the trenches 6a and 6b.

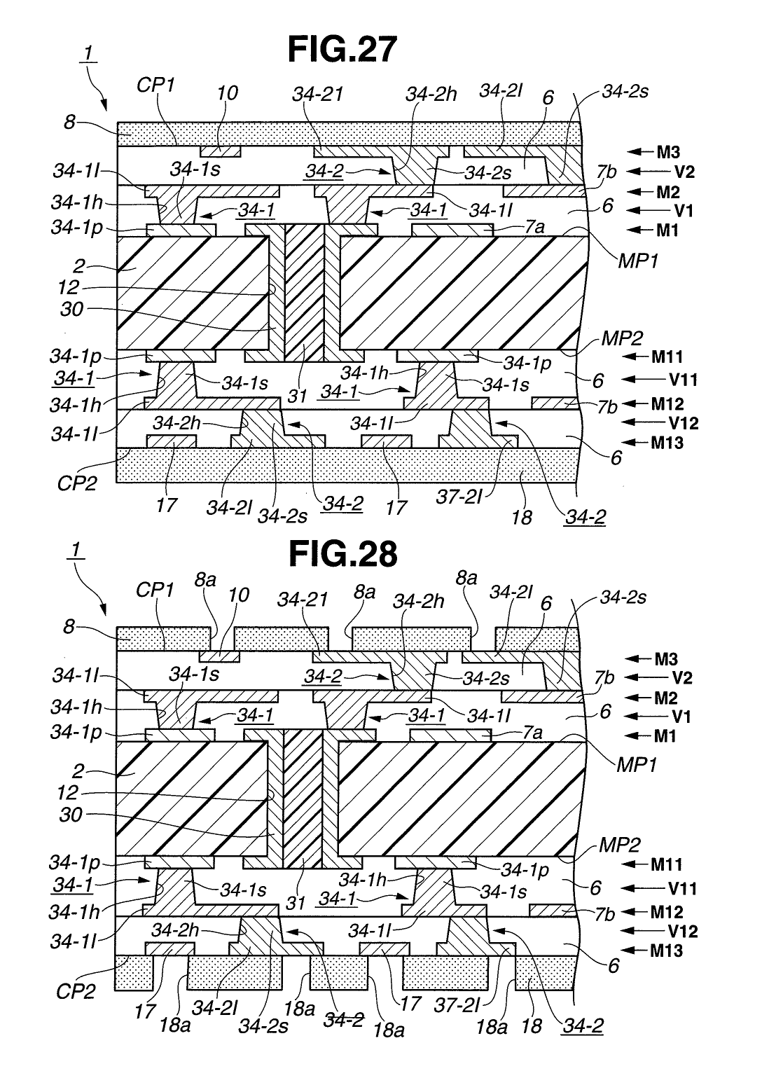

The thus-obtained conduction layers M2 and M12 are subjected to roughening treatment. After that, the insulation layers V2 and V12 are formed by laminating films of the resin composition 6 on the conduction layers M2 and M12 so as to cover the conduction layers M2 and M12 (wiring lines 7b and filled vias 34-1) with the films of the resin composition 6, and then, hardening the films of the resin composition 6 as shown in FIG. 24. The filler may also be contained in the resin composition 6 as needed.

As shown in FIG. 25, the outer main surfaces of the insulation layers V2 and V12 are subsequently irradiated with a laser to thereby form the via holes 34-2h and trenches in the insulation layers V2 and V12 according to a predetermined pattern. Then, the insulation layers V2 and V12 with the via holes 34-2h and trenches are subjected to roughening treatment. When the filler is contained in the insulation layers V2 and V12, the filler is liberated on the insulation layers V2 and V12 by the roughening treatment and then removed by water washing treatment (e.g. high-pressure water washing) and air blowing treatment etc. as appropriate as mentioned above. Further, the insides of the via holes 34-2h are cleaned by desmear treatment and outline etching treatment.

As shown in FIG. 26, the patterned conduction layers M3 and M13 are obtained by forming the via conductors 34-2s, the via lands 34-2l, the metal terminal pads 10 and 17 subsequently on the insulation layers V2 and V12 in the same manner as above (see paragraphs [0050] to [0070] and FIGS. 11 to 24).

The solder resist layers 8 and 18 are formed on the conduction layers M3 and M13 as shown in FIG. 27. As shown in FIG. 28, the openings 8a and 18a are made in the resist layers 8 by resist application, exposure and development so that the metal terminal pads 10 and 17 and the via lands 34-2l are exposed through the openings 8a and 18a.

The laminated films 10a and 17a are formed as conduction layers by electroless plating on the exposed metal terminal pads 10 and 17 and via lands 34-2l. After that, the solder bumps 11 are formed on the laminated films 10a in the openings 8a to establish electrical connection to the metal terminal pads 10 and to the via lands 34-2l.

In this way, the wiring board 1 of FIGS. 1 to 4 is completed.

As described above, it is possible in the wiring board 1 to form the conduction layer M2, M12, M3, M13 uniformly in the openings (the via holes 34-1h, 34-2h and the trenches 6a, 6b) of the resin insulation layer V1, V11, V2, V12 irrespective of the width or diameter (area) of the openings and without complicated process steps. Especially when the openings (the via holes 34-1h, 34-2h and the trenches 6a, 6b) are 100 μm or larger in width or diameter, the above effects of the present invention becomes more pronounced as compared to the case where a conduction layer is formed by plating in openings of a resin insulation layer.

The entire contents of Japanese Patent Application No. 2010-248562 (filed on Nov. 5, 2010) and No. 2010-248563 (filed on Nov. 5, 2011) are herein incorporated by reference.

Although the present invention has been described with reference to the above specific embodiment of the invention, the present invention is not limited to this exemplary embodiment. Various modification and variation of the embodiment described above will occur to those skilled in the art in light of the above teachings.

For example, the via holes 34-1h may be formed after the formation of the trenches 6a and 6b although the trenches 6a and 6b are formed after the formation of the via holes 34-1h in the above embodiment. In this case, however, the processing residue occurring in the insulation layers V1 and V11 during the formation of the via holes 34-1h and remaining on the bottoms of the via holes 34-1h cannot be removed and cleaned up by the surface irradiation with the excimer laser. It is thus difficult to omit the water washing during the desmear treatment or the subsequent air blowing treatment so that the manufacturing process of the wiring board 1 becomes somewhat complicated.

The scope of the invention is defined with reference to the following claims.

What is claimed is:

1. A method of manufacturing a wiring board, the wiring board comprising at least one conduction layer and at least one resin insulation layer, the method comprising:
an opening forming step of forming openings in a main surface of the resin insulation layer; and
a paste filling step of filling a copper paste into the openings to form the conduction layer from the copper paste.

2. The method according to claim 1, further comprising: before the paste filling step, an undercoat applying step of applying a copper undercoat layer into the openings.

3. The method according to claim 1, wherein, in the paste filling step, the copper paste is filled into the openings by at least one selected from the group consisting of a squeegee process, a roll coater process, a spray coater process, a curtain coater process, a slit coater process, a dip coater process, a gravure coater process and a die coater process.

4. The method according to claim 3, wherein the copper paste is fed to a main surface of the resin insulation layer in the paste filling step; and wherein the method further comprises a polishing step of polishing the copper paste fed to the main surface of the resin insulation layer.

5. The method according to claim 1, wherein the copper paste is filled into the openings by an ink-jet process using an ink jet device in the paste filling step.

6. The method according to claim 5, wherein the ink jet device has at a tip end portion thereof a discharge hole from which the copper paste is discharged; and wherein the paste filling step includes starting discharging the Cu paste into the opening through the discharge hole of the ink-jet device in a state that the discharge hole is located within the opening.

7. The method according to claim 5, wherein the openings include wiring trenches and via holes that are different in depth from each other; and wherein the paste filling step includes filling the Cu paste by the ink-jet device into the via holes, and then, filling the Cu paste by the ink-jet device into the wiring trenches.

8. The method according to claim 5, wherein the ink jet device is at least one of a thermal ink-jet device and a piezoelectric ink-jet device.

9. The method according to claim 1, wherein the openings have a width or diameter of 100 μm or more.
